(19) United States
(12) Patent Application Publication
(10) Pub. No.: US 2008/0278182 A1
(43) Pub. Date: Nov. 13, 2008

(54) Test Structure for Statistical Characterization of Metal and Contact/Via Resistances

(76) Inventors: Kanak B. Agarwal, Austin, TX (US); Ying Liu, Austin, TX (US); Sani R. Nassif, Austin, TX (US)

Correspondence Address: IBM CORPORATION (JVM), C/O LAW OFFICE OF JACK V. MUSGROVE, 2911 BRIONA WOOD LANE, CEDAR PARK, TX, 78613, US

(21) Appl. No.: 11/746,766

(22) Filed: May 10, 2007

(51) Int. Cl. G01R 27/08

(52) U.S. Cl. 324/713

(57) ABSTRACT

A test structure for measuring resistances of a large number of interconnect elements such as metal, contacts and vias includes an array of test cells in rows and columns. Power is selectively supplied to test cells in a given column while current is selectively steered from test cells in a given row. A first voltage near the power input node of a device under test (DUT) is selectively sensed, and a second voltage near the current measurement tap is selectively sensed. The resistance of the DUT is the difference of the first and second voltages divided by the current. Additional voltage taps are provided for test cells having multiple resistive elements. This array of test cells can be used to characterize the statistical distribution of resistance variation and to identify physical location of defects in resistive elements.

### BACKGROUND OF THE INVENTION

1. Field of the Invention

The present invention generally relates to the design and testing of integrated circuits, and more particularly to a method and system for testing an array of resistive elements such as metal wiring, diffusion-to-metal contacts or inter-metal vias formed on an integrated circuit.

2. Description of the Related Art

Integrated circuits are used for a wide variety of electronic applications, from simple devices such as wristwatches, to the most complex computer systems. A microelectronic integrated circuit (IC) chip can generally be thought of as a collection of logic cells with electrical interconnections between the cells, formed on a semiconductor substrate (e.g., silicon). An IC may include a very large number of cells and require complicated connections between the cells. A cell is a group of one or more circuit elements such as transistors, capacitors, resistors, inductors, and other basic circuit elements grouped to perform a logic function. The wires connecting the cells are formed on the surface of the chip. For more complex designs, there may be more than ten distinct layers of conducting media available for routing, including a polysilicon layer, a diffusion layer, and multiple metal layers (metal-1, metal-2, metal-3, etc.). The polysilicon layer, diffusion layer and metal layers can all be used for routing. Contacts connect the diffusion and polysilicon layers to the metal-1 layer, and vias interconnect the metal layers.

An IC chip is fabricated by first conceiving the logical circuit description, and then converting that logical description into a physical description, or geometric layout. This process is usually carried out using a “netlist,” which is a record of all of the nets, or interconnections, between the cell pins. A layout typically consists of a set of planar geometric shapes in several layers. The layout is then checked to ensure that it meets all of the design requirements, particularly timing requirements. The result is a set of design files known as an intermediate form that describes the layout. The design files are then converted into pattern generator files that are used to produce patterns called masks by an optical or electron beam pattern generator. During fabrication, these masks are used to pattern one or more dies on a silicon wafer using a sequence of photolithographic steps. The process of converting the specifications of an electrical circuit into a layout is called the physical design.

Cell placement in semiconductor fabrication involves a determination of where particular cells should optimally (or near-optimally) be located on the surface of a integrated circuit device. Due to the large number of components and the details required by the fabrication process for very large scale integrated (VLSI) devices, physical design is not practical without the aid of computers. As a result, most phases of physical design extensively use computer-aided design (CAD) tools, and many phases have already been partially or fully automated. Automation of the physical design process has increased the level of integration, reduced turn around time and enhanced chip performance. Several different programming languages have been created for electronic design automation (EDA), including Verilog, VHDL and TDML. A typical EDA system receives one or more high level behavioral descriptions of an IC device, and translates this high level design language description into netlists of various levels of abstraction.

Faster performance and predictability of responses are elements of interest in circuit designs. As process technology scales to the nanometer regime, it is becoming increasingly important for the performance and reliability of IC chips and systems to understand how variations in process parameters affect the operation of an electronic device or circuit. A designer needs to model device characteristics such as resistance/capacitance measurements for wiring. In particular, back-end of the line (BEOL) variations, i.e., at the interconnect level, are becoming more significant. There are large variations in metal, contact and via resistances that can have an adverse impact on manufacturing yield and circuit reliability. Open failures can also arise in contacts and vias due to manufacturing defects, electromigration, or thermal-stress migration. It is extremely important to be able to characterize the statistical distribution of metal and contact/via resistances and identify potentially faulty locations in an integrated circuit design. This problem is growing as contact resistances are increasing rapidly due to technology scaling down (resulting in a smaller cross-sectional area for conduction), and the range of contact resistances is growing as well. Contact/via resistance may vary systematically depending on the micro-environment (e.g., spacing, metal overlap, number of contacts, etc.), and may also vary in a random manner.

The testing technique commonly used for contact or via characterization utilizes chain structures. The chain structures have many resistive elements connected in a serial fashion. For example, there may be millions of diffusion-to-metal-1 contacts with a measurement tap after every hundred or so. This technique cannot be used to measure an individual element's resistance in the presence of variations because it simply averages any variation between two taps. Thus the technique is only useful in detecting failures, and even then it is difficult to determine exactly how many contacts failed and their physical locations. This approach also requires an unduly large area.

One technique which can be used to measure individual contact or via resistance utilizes Kelvin structures. A typical Kelvin structure for resistance measurement has a four-terminal cross bridge interconnecting four pads on two different metal layers. Two of the pads are connected to the central contact by metal sections, and the other two pads are connected to the central contact by the diffusion layer. Contact resistance is determined by forcing current between two selected pads and measuring the voltage across those pads. Although these structures measure contact resistance the most directly, the measurement results can be adversely influenced by effects from alignment and the enlarged diffused region around the contact. Furthermore, this technique is not sufficient for statistical characterization of resistance distribution which requires a very large number of measurements. In order to reliably characterize such variabilities hundreds of samples are needed, which is impractical using Kelvin structures given the limited number of input/output (C4) pads provided on the circuits.

Circuit designers make assumptions about process variations of parameters which have a significant impact on product performance, but there is no reliable system for verifying these assumptions. Without knowing the distribution of contact resistance designers must use excessive guard bands, and it is harder to evaluate any negative impact on design rule recommendations (such as mandatory usage of double contacts). It would, therefore, be desirable to devise an improved testing structure that could measure the statistical spread of resistive elements. It would be further advantageous if the test system could measure these variations with high accuracy and nominal resource cost.

### SUMMARY OF THE INVENTION

It is therefore one object of the present invention to provide an improved method of testing metal and contact resistances in an integrated circuit.

It is another object of the present invention to provide such a method which is capable of testing a large array of such resistive elements.

It is yet another object of the present invention to provide a circuit test structure for metal and contact/vias which takes into account systemic variations in measurements caused by the micro-environment.

The foregoing objects are achieved in a method of testing interconnect structures arranged in rows and columns in an integrated circuit, by selectively connecting a supply voltage to power input nodes of a first plurality of the interconnect structures which are arranged in a column (and include an interconnect structure under test), selectively measuring current from output nodes of a second plurality of interconnect structures which are arranged in a row (and also include the interconnect structure under test), sensing a first voltage near the power input node of the interconnect structure under test, sensing a second voltage near the output node of the interconnect structure under test, and deriving a resistance for the interconnect structure under test based on a difference of the first and second voltages divided by the current. The resistance may be adjusted by subtracting a separately measured resistance of another resistive element along the row in the current path. Gating control signals for the power input nodes of interconnect structures in other (non-selected) columns are preferably clamped to electrical ground. A test circuit for carrying out the method may advantageously utilize pass gates located at the top and bottom of the test array to control power selection transistors which couple the power input nodes for a given column of interconnect structures to a vertical power rail and to control sense selection transistors which couple the power input nodes to horizontal sense lines; the test circuit may further utilize switching transistors located at the left and right sides of the test array to selectively connect the row lines to a plurality of measurement taps. In a specific embodiment the interconnect structure includes a first resistive element extending along a metal layer of the integrated circuit, and a second resistive element extending from the diffusion layer to the metal layer.

The above as well as additional objectives, features, and advantages of the present invention will become apparent in the following detailed written description.

### BRIEF DESCRIPTION OF THE DRAWINGS

The present invention may be better understood, and its numerous objects, features, and advantages made apparent to those skilled in the art by referencing the accompanying drawings.

FIG. 1 is a schematic diagram of a test cell constructed in accordance with one embodiment of the present invention, used in measuring metal and contact resistances;

FIG. 2 is a plan view of a portion of an integrated circuit illustrating the diffusion, contact and metal layers for the embodiment of the test cell illustrated in FIG. 1;

FIG. 3 is a schematic diagram of a test circuit constructed in accordance with one embodiment of the present invention with multiple test cells arranged in addressable rows and columns; and

FIG. 4 is a block diagram of a test system constructed in accordance with one embodiment of the present invention which uses the test circuit of FIG. 3.

The use of the same reference symbols in different drawings indicates similar or identical items.

### DESCRIPTION OF THE PREFERRED EMBODIMENT(S)

The present invention is directed to an improved method and apparatus for measuring resistive elements in an integrated circuit, such as metal and contact/vias. Test structures made in accordance with the present invention afford accurate characterization of resistance variation wherein each resistive element can effectively be measured individually. The test structures feature a large array of densely populated contact test cells.

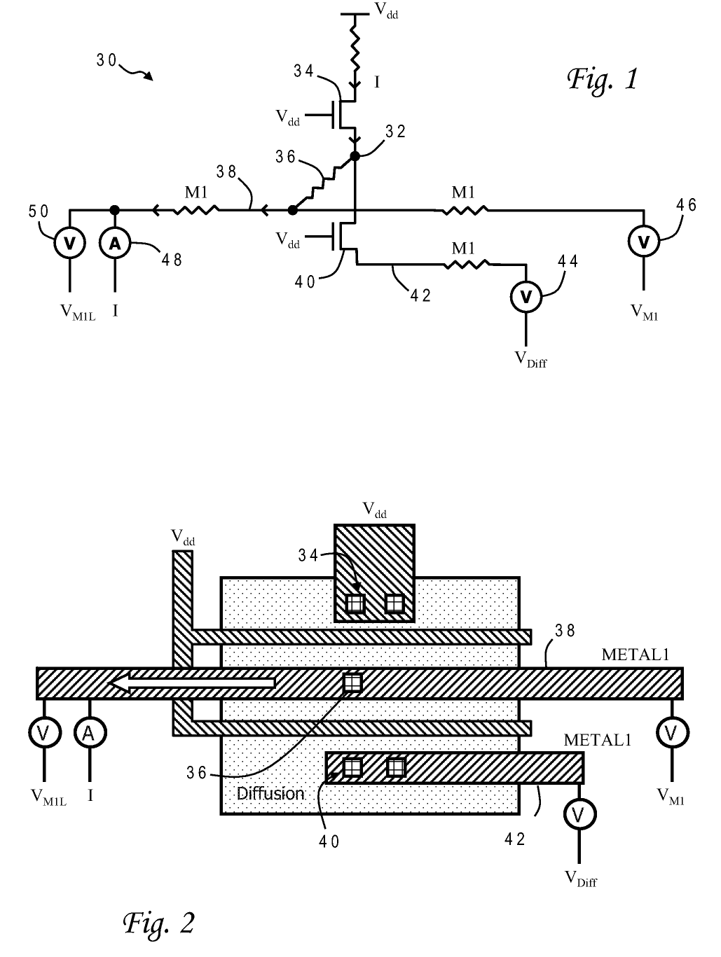

With reference now to the figures, and in particular with reference to FIG. 1, there is depicted one embodiment 30 of a test cell constructed in accordance with the present invention. Test cell 30 is generally comprised of a first selection transistor 34 (power selection transistor) whose drain is connected to a power supply voltage V_{dd} and whose source is connected to a power input node 32, a contact/via 36 having one end connected to the source of first selection transistor 34 and having another end connected to a first section 38 of a metal layer (M1), and a second selection transistor 40 (sense selection transistor) whose drain is connected to power input node 32 and whose source is connected to a second section 42 of the metal layer. Four measurement nodes 44, 46, 48, and 50 are provided to measure the voltage at different locations in test cell 30 as well as the current flowing through contact 36. Measurement node 44 is connected to second metal section 42 and is adapted for connection to a voltage sensor to derive a voltage V_{Diff} corresponding to the diffusion potential near the interconnection between contact 36 and source diffusion of the first selection transistor 34. Measurement node 46 is connected to the right side of first metal section 38 and is adapted for connection to a voltage sensor to derive a voltage V_{M1} corresponding to the metal potential near the internal node between contact 36 and first metal section 38. Measurement node 48 (a current sink) is connected to the left side of first metal section 38 and is adapted for connection to a current sensor to derive a current I that flows through test cell 30. Measurement node 50 is also connected to the left side of first metal section 38 and is adapted for connection to a voltage sensor to derive a voltage V_{MIL} corresponding to the metal potential near the current measurement tap. In this embodiment transistors 34 and 40 are n-type transistors, but the test cell can alternatively be implemented with p-type transistors having inverted control signals.

FIG. 2 is a plan view of test cell 30 within the integrated circuit, representing an exemplary layout of the various conducting layers. In this view the diffusion layer is at the bottom, the metal-1 layer is at the top, and the polysilicon (gate) layer is between the diffusion and metal-1 layers. The polysilicon layer is connected to the power supply V_{dd} by one or more additional metal layers which are not shown. Contact 36 thus extends through the diffusion layer to the metal-1 layer. Current is steered through a selected test cell by controlling the gate signal of first selection transistor 34, and the resistances of contact 36 (R_{CA}) and first metal section 38 (R_{M1}) can be computed using Ohms law based on the measured steady-state values, i.e.,

R_{CA}=(V_{Diff}−V_{M1})/I, and

R_{M1}=(V_{M1}−V_{MIL})/I.

The overall resistance for the interconnect structure of test cell 30 is the sum of the contact and M1 resistances, and can alternatively be computed as Rₜₒₜₐₗ=(V_{Diff}−V_{MIL})/I. FIG. 2 shows the approach for a diffusion-to-metal contact but the invention can easily be used for inter-metal vias as well.

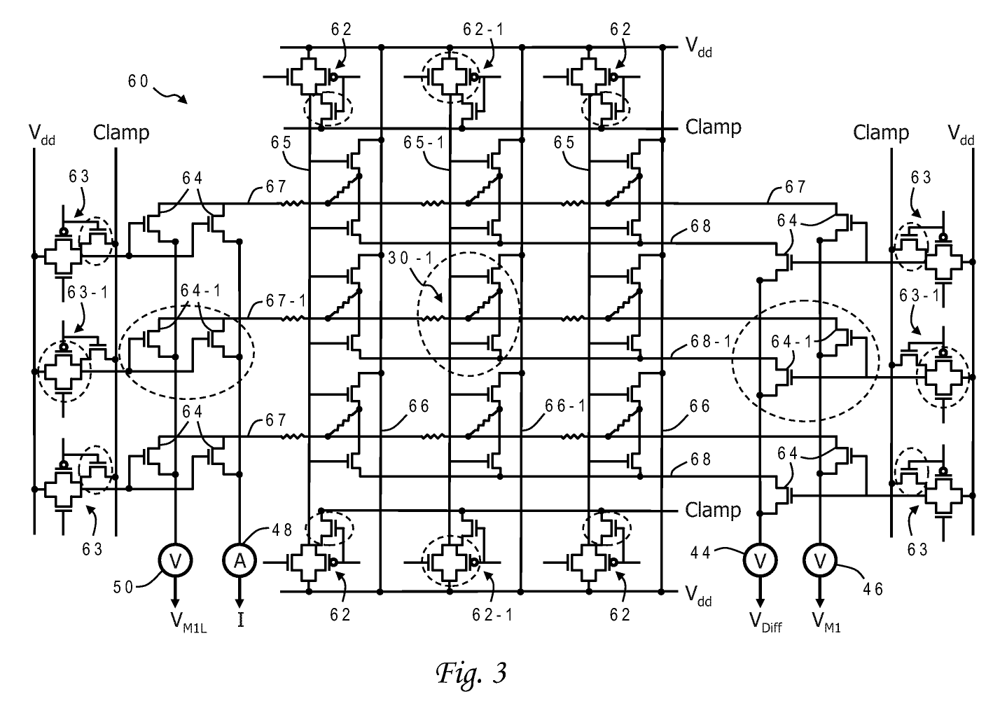

A test circuit constructed in accordance with the present invention may utilize a plurality of test cells 30 arranged in an addressable array of rows and columns as further illustrated in FIG. 3. Test circuit 60 is formed in an integrated circuit (IC) chip and, in this simplified embodiment, has nine test cells 30 arranged in a 3×3 matrix. Power selection transistors are controlled by pass gates 62 along the top and bottom of the cell matrix, and pass gates 63 and switching transistors 64 at the left and right sides of the matrix are used to connect the measurement taps to a particular test cell.

Operation of test circuit 60 may be understood with reference to an example wherein the center test cell 30-1 is the device under test (DUT). For this DUT, voltage is supplied by turning on the pass gates 62-1 which feed the supply voltage V_{dd} (e.g., 1 volt) to a column line 65-1 connected to the gates of the selection transistors in test cell 30-1. The drains of the power selection transistors are connected to vertical power rails 66 which are in turn connected to the supply voltage line, and the sources of the sense selection transistors are connected to horizontal sense lines 68. The remaining pass gates 62 are turned off, preventing power from being supplied to the test cells in the left and right columns. Each pass gate includes an nfet/pfet transistor pair which couples a column line 65 to the voltage supply when the pass gate is on, and includes another transistor which couples a column line 65 to a clamp line (i.e., electrical ground) when the pass gate is off.

Activation of pass gate 62-1 feeds power from vertical power rail 66-1 to the chosen test cell and to every other test cell in the middle column, but only the outputs of DUT 30-1 are coupled to the measurement taps by turning on switching transistors 64-1 for the chosen row. Switching transistors 64-1 are turned on by activating pass gates 63-1. Two of the switching transistors 64-1 on the left side of the array connect a row line 67-1 to the current and V_{MIL} taps, and two other switching transistors 64-1 on the right side of the array connect a sense line 68-1 to the V_{Diff} tap and row line 67-1 to the V_{M1} tap The remaining switching transistors 64 are turned off (i.e., pass gates 63 are turned off) to leave open connections on the row lines 67 and the sense lines 68 for cells (rows) that are not under test. Each relevant transistor which is turned on specifically for testing DUT 30-1 is indicated in FIG. 3 by a dashed oval.

The resulting resistance measurement for R_{M1} will include the additional resistance from all metal to the left of the test cell (along the current path from the given DUT to the current measurement tap), so this measurement is adjusted by subtracting the resistance value for the metal contribution from the left test cell (separately measured) to arrive at the actual resistance for the metal in test cell 30-1. The measurement can also be divided by the number of metal sections in the current path to provide an average (normalized) resistance.

This array of test cells can be used to characterize the impact of different layouts on metal and contact/via resistance by varying parameters such as poly spacing, contact size, number of contacts, contact density, and metal overlap. The stress related failures in the interconnect structures can also be characterized through stress tests.

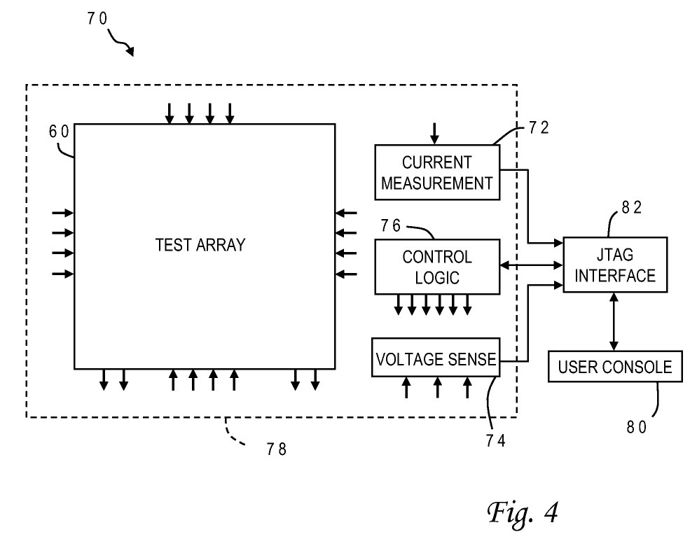

Referring now to FIG. 4, test circuit 60 is employed in a test system 70 which also includes a current measurement unit 72, a voltage sense unit 74, and control logic 76 formed in the same IC chip 78 which contains test circuit 60. Control logic 76 may for example include scan latches as described more fully in U.S. patent application Ser. No. 11/422,913 filed Jun. 8, 2006, which is hereby incorporated. The scan latches are set by a test program running on a workstation or user console 80 through an interface port such as a JTAG interface 82. Each cell in the array is tested by activating the appropriate pass gates 62, 63 using the control logic latches to select the first column and first row and then sequentially moving to other rows and columns. The voltage and current measurements are also transmitted to user console 80 via JTAG interface 82. The test program running at the console records the measurements and then computes the resistances as explained above, and outputs the results to the user. The size of the array may vary; although only three rows and three columns are shown, an exemplary array might have 1,000 columns and 1,000 rows, for a total of one million testable interconnect devices.

The present invention thus provides the capability to measure individual metal and contact/via resistances accurately as well as measuring resistance distribution in the same micro-environment in which the interconnects are used. This capability includes isolating the exact location of any failing contact, which can then be followed up with failure analysis for detailed investigations. The measurements are provided for a large number of interconnect devices without corruption by spurious sneak currents or diffusion resistance. The test structure taught herein is also useful as a test vehicle for simultaneous measurement of FEOL and BEOL characteristics, wherein the characteristics of the power selection transistors can he measured.

Although the invention has been described with reference to specific embodiments, this description is not meant to be construed in a limiting sense. Various modifications of the disclosed embodiments, as well as alternative embodiments of the invention, will become apparent to persons skilled in the art upon reference to the description of the invention. For example, the test cell has been described in the context of an interconnection having a single via and a single metal component, but other combinations of resistive elements with additional voltage measurement taps may be provided. It is therefore contemplated that such modifications can be made without departing from the spirit or scope of the present invention as defined in the appended claims.

What is claimed is:

1. A method of testing interconnect structures arranged in rows and columns in an integrated circuit, comprising:
selectively connecting a supply voltage to power input nodes of a first plurality of the interconnect structures which are arranged in a column, the first plurality of interconnect structures including an interconnect structure under test;
selectively measuring current from output nodes of a second plurality of interconnect structures which are arranged in a row, the second plurality of interconnect structures including the interconnect structure under test;
sensing a first voltage near the power input node of the interconnect structure under test;
sensing a second voltage near the output node of the interconnect structure under test; and
deriving a resistance for the interconnect structure under test based on a difference of the first and second voltages divided by the current.

2. The method of claim 1, further comprising adjusting the resistance by subtracting a separately measured resistance of a resistive element in another interconnect structure in the row.

3. The method of claim 1 wherein:
power selection transistors couple power input nodes of the interconnect structures to the supply voltage; and
gates of power selection transistors of interconnect structures in other columns are selectively clamped to electrical ground.

4. The method of claim 1 wherein:
the interconnect structures are arranged in a test array having top, bottom, left and right sides;
pass gates located at the top and bottom sides of the test array control power selection transistors which couple the power input nodes of the first plurality of interconnect structures to a vertical power rail; and
switching transistors located at the left and right sides of the test array selectively connect the power input nodes and output nodes of the second plurality of interconnect structures to a plurality of measurement taps.

5. The method of claim 1 wherein the resistance is a first resistance and the interconnect structure under test has at least two resistive elements connected in series, and further comprising:
sensing a third voltage at an internal node between the two resistive elements; and
deriving a second resistance for the interconnect structure under test based on a difference of the second and third voltages divided by the current.

6. The method of claim 5 wherein the resistive elements include:
a first resistive element extending along a first layer of the integrated circuit; and
a second resistive element connecting the first layer of the integrated circuit to a second layer of the integrated circuit.

7. The method of claim 6 wherein:
the first layer is a metal layer; and
the second layer is a diffusion layer.

8. A test circuit comprising:
an array of interconnect structures arranged in rows and columns in an integrated circuit, each interconnect structure having an input node and an output node;
means for selectively connecting a supply voltage line to input nodes of interconnect structures in a given column;
means for selectively steering current from output nodes of interconnect structures in a given row to a current measurement tap and a first voltage tap; and
means for selectively connecting an input node of an interconnect structure under test located in the given row and in the given column to a second voltage tap.

9. The test circuit of claim 8 wherein said means for connecting the supply voltage line to the input nodes includes:
a plurality of vertical voltage rails, one for each column;
a plurality of selection transistors coupling the input nodes to the vertical voltage rails; and
a plurality of pass gates which control said selection transistors.

10. The test circuit of claim 9 wherein gates of selection transistors for interconnect structures in columns other than the given column are selectively clamped to electrical ground.

11. The test circuit of claim 8 wherein said means for selectively steering current includes:
a plurality of row lines, one for each row;
a plurality of switching transistors coupling the row lines to the current measurement tap and the first voltage tap; and
a plurality of pass gates which control said switching transistors.

12. The test circuit of claim 8 wherein said means for selectively connecting the power input node to the second voltage tap includes:
a plurality of sense lines, one for each row;
a plurality of switching transistors coupling the sense lines to the second voltage tap; and
a plurality of pass gates which control said switching transistors.

13. The test circuit of claim 8, further comprising:
a current measurement unit in the integrated circuit which measures a current at the current measurement tap;
a voltage sense unit in the integrated circuit which senses a first voltage at the first voltage tap and senses a second voltage at the second voltage tap; and
control logic in the integrated circuit which controls the selection of the given column and the given row.

14. A test system which uses the test circuit of claim 13, and further comprising:
a user console having a test program which sets selection latches in said control logic and derives a resistance for the interconnect structure under test based on a difference of the first and second voltages divided by the current; and
an interface connecting said user console to said current measurement unit, said voltage sense unit, and said control logic.

15. The test circuit of claim 8 wherein the interconnect structure under test has at least two resistive elements connected in series, and further comprising means for selectively connecting an internal node between the two resistive elements to a third voltage tap.

16. The test circuit of claim 15 wherein the resistive elements include:
a first resistive element extending along a first layer of the integrated circuit; and
a second resistive element connecting the first layer of the integrated circuit to a second layer of the integrated circuit.

17. The test circuit of claim 16 wherein
the first layer is a metal layer; and
the second layer is a diffusion layer.

18. A test circuit comprising:
a supply voltage line;
a plurality of vertical voltage rails connected to said supply voltage line;
a plurality of horizontal sense lines;
an array of test cells arranged in rows and columns, each test cell having two resistive elements connected in series, a power selection transistor coupling an input node of the resistive elements to one of said vertical voltage rails, and a sense selection transistor coupling the input node to one of said horizontal sense lines;
a plurality of column lines, each column line being connected to gates of power selection transistors and gates of sense selection transistors in a corresponding column of said test cells;
a first plurality of pass gates which couple said column lines to said supply voltage line;
a plurality of row lines, each row line being connected to output nodes of resistive elements in a corresponding row of said test cells;
a first plurality of switching transistors coupling said row lines to a current measurement tap at a first side of said array;
a second plurality of switching transistors coupling said row lines to a first voltage measurement tap proximate the current measurement tap;
a third plurality of switching transistors coupling said row lines to a second voltage measurement tap at a second side of said array opposite the first side;
a fourth plurality of switching transistors coupling said sense lines to a third voltage measurement tap;
a second plurality of pass gates which couple gates of said first, second, third and fourth pluralities of switching transistors to said supply voltage line,
a current measurement unit which measures a current at the current measurement tap;
a voltage sense unit which senses first, second and third voltages respectively at the first, second and third voltage taps; and
control logic which selectively activates said first and second pluralities of pass gates.

19. The test circuit of claim 18 wherein each test cell has:
a first resistive element extending along a metal layer of the integrated circuit; and
a second resistive element connecting the metal layer to a diffusion layer of the integrated circuit.

20. A test system which uses the test circuit of claim 18, and further comprising
a user console having a test program which sets selection latches in said control logic, derives a first resistance for a cell under test based on a difference of the first and second voltages divided by the current and derives a second resistance for the cell under test based on a difference of the second and third voltages divided by the current; and
an interface connecting said user console to said current measurement unit, said voltage sense unit, and said control logic.
